(19) United States
(12) Patent Application Publication
(10) Pub. No.: US 2012/0138967 A1
(43) Pub. Date: Jun. 7, 2012

(54) LED PACKAGE AND METHOD FOR MANUFACTURING THE SAME

(75) Inventors: Satoshi Shimizu, Fukuoka-ken (JP); Iwao Matsumoto, Fukuoka-ken (JP); Kazuhiro Tamura, Fukuoka-ken (JP); Takayuki Yasuzumi, Fukuoka-ken (JP)

(73) Assignee: KABUSHIKI KAISHA TOSHIBA, Tokyo (JP)

(21) Appl. No.: 13/189,654

(22) Filed: Jul. 25, 2011

(30) Foreign Application Priority Data
Dec. 7, 2010 (JP) 2010-272347

(51) Int. Cl. H01L 33/08

(52) U.S. Cl. 257/88; 438/28; 257/E33.012

(57) ABSTRACT

An LED package includes: 2n lead frames (n is a natural number); n LED chips provided above the 2n lead frames, one terminal of each of the n LED chips being connected to each of the n lead frames, another terminal of each of the n LED chips being connected to each of other n lead frames; a wire connected between the terminal and one of the lead frames; and a resin body covering the n LED chips, the wire, and a part of each of the 2n lead frames. The each of the 2n lead frames includes; a base having an upper surface and side surfaces, the upper surface and the side surfaces being covered with the resin body; and a plurality of extending portions extending from the base, one of the extending portions having tip surface which is exposed at one side surface of the resin body, another of the extending portions having tip surface which is exposed at another side surface of the resin body, the one side surface and the another side surface being perpendicular to each other, and. An outer shape of the resin body forms an outer shape of the LED package.

### CROSS-REFERENCE TO RELATED APPLICATIONS

This application is based upon and claims the benefit of priority from the prior Japanese Patent Application No. 2010-272347, filed on Dec. 7, 2010; the entire contents of which are incorporated herein by reference.

### FIELD

Embodiments described herein relate generally to an LED package and a method for manufacturing the same.

### BACKGROUND

Conventionally, in an LED package that mounts LED chips, a bowl-shaped envelope formed of white resin has been provided, the LED chips have been mounted on a bottom surface of the envelope, and transparent resin has been encapsulated inside the envelope to embed the LED chips for the purpose of controlling a light distribution characteristic to increase light extraction efficiency from the LED package. Additionally, the envelopes have been formed of polyamide series thermoplastic resin in many cases.

However, in recent years, higher durability of the LED packages has been requested along with an expanding application range of the LED packages. Meanwhile, light and heat, emitted from the LED chips increase along with higher output of the LED chips, and thereby resin portions that seal the LED chips have become easily deteriorated. In addition, further reduction in cost has been requested along with the expanding application range of the LED packages.

### BRIEF DESCRIPTION OF THE DRAWINGS

FIG. 1 is a perspective view illustrating an LED package according to a first embodiment;

FIG. 2A is a plan view illustrating the LED package according to the first embodiment, and FIG. 2B is a cross-sectional view taken along a line A-A′ shown in FIG. 2A;

FIG. 3 is a flow chart illustrating a method for manufacturing the LED package according to the first embodiment;

FIGS. 4A to 6B are cross-sectional views of processes illustrating the method for manufacturing the LED package according to the first embodiment;

FIG. 7A is a plan view illustrating a lead frame sheet in the first embodiment, and FIG. 7B is a partial enlarged plan view illustrating an element region of this lead frame sheet;

FIGS. 8A to 8H are cross-sectional views of processes illustrating a method for forming the lead frame sheet in a variation of the first embodiment;

FIG. 9 is a plan view illustrating an LED package according to a second embodiment;

FIG. 10 is a plan view illustrating an LED package according to a third embodiment; and

FIG. 11 is a plan view illustrating an LED package according to a forth embodiment.

### DETAILED DESCRIPTION

In general, according to one embodiment, An LED package includes: 2n lead frames (n is a natural number); n LED chips provided above the 2n lead frames, one terminal of each of the n LED chips being connected to each of the n lead frames, another terminal of each of the n LED chips being connected to each of other n lead frames; a wire connected between the terminal and one of the lead frames; and a resin body covering the n LED chips, the wire, and a part of each of the 2n lead frames. The each of the 2n lead frames includes; a base having an upper surface and side surfaces, the upper surface and the side surfaces being covered with the resin body; and a plurality of extending portions extending from the base, one of the extending portions having tip surface which is exposed at one side surface of the resin body, another of the extending portions having tip surface which is exposed at another side surface of the resin body, the one side surface and the another side surface being perpendicular to each other, and. An outer shape of the resin body forms an outer shape of the LED package.

According to another embodiment, an LED package includes: 2n lead frames (n is a natural number) separated from one another; n LED chips provided above the 2n lead frames, one terminal of each of the n LED chips being connected to each of the n lead frames, another terminal of each of the n LED chips being connected to each of other n lead frames; a wire connected between the terminal and one of the lead frames; and a resin body covering the n LED chips, the wire, and a part of each of the 2n lead frames. The each of the 2n lead frames includes; a base having an upper surface and side surfaces, the upper surface and the side surfaces being covered with the resin body; and a extending portion extending from the base, a tip surface of the extending portion is exposed at a side surface of the resin body, the side surface being located in one direction when viewed from the base. The wire is bonded to the lead frame by applying with ultrasonic wave, a direction of vibration of the ultrasonic wave being parallel to the one direction. An outer shape of the resin body forms an outer shape of the LED package.

According to another embodiment, a method for manufacturing an LED package includes: mounting n LED chips (n is a natural number) for each of a plurality of element regions provided on a lead frame sheet, connecting one terminal of each of the n LED chips to each of n lead frames of 2n lead frames, and connecting another terminal of each of the n LED chips to each of another n lead frames of the 2n lead frames, the lead frame sheet being formed of a conductive material, the lead frame sheet having a basic pattern including the plurality of element regions arranged in a matrix configuration, the lead frame sheet including support members which are provided in dicing regions between the element regions, each of the element regions including the 2n lead frames, each of the 2n lead frames being separated from one another, each of the 2n lead frames including a base and coupling portions, the base being separated from outer edges of the element regions, the coupling portions extending from the base and coupled to one of the support members, forming a resin plate, the resin plate covering the LED chips and a part of the lead frame sheet, a lower surface of the resin plate being on a same plane as a lower surface of the lead frame sheet; and dividing portions arranged in the element regions on the lead frame sheet and the resin plate into individual pieces by removing portions arranged in the dicing regions on the lead frame sheet and the resin plate. One of a plurality of the coupling portions reach one side of outer edges of the element regions, and another of the plurality of the coupling portions reach another side of outer edges of the element regions, the one side and the another side being perpendicular to each other. The connecting the terminal includes; applying ultrasonic wave to one end of a wire to bond the one end to the lead frame, and bonding another end of the wire to the terminal. An outer shape of the portion divided into the individual pieces forms an outer shape of the LED package.

According to another embodiment, a method for manufacturing an LED package includes: mounting n LED chips (n is a natural number) for each of a plurality of element regions provided on a lead frame sheet, connecting one terminal of each of the n LED chips to each of n lead frames of 2n lead frames, and connecting another terminal of each of the n LED chips to each of another n lead frames of the 2n lead frames, the lead frame sheet being formed of a conductive material, the lead frame sheet having a basic pattern including the plurality of element regions arranged in a matrix configuration, the lead frame sheet including support members which are provided in dicing, regions between the element regions, each of the element regions including the 2n lead frames, each of the 2n lead frames being separated from one another, each of the 2n lead frames including a base and coupling portions, the base being separated from outer edges of the element regions, the coupling portions extending from the base and coupled to one of the support members, forming a resin plate, the resin plate covering the LED chips and a part of the lead frame sheet, a lower surface of the resin plate being on a same plane as a lower surface of the lead frame sheet; and dividing portions arranged in the element regions on the lead frame sheet and the resin plate into individual pieces by removing portions arranged in the dicing regions on the lead frame sheet and the resin plate. The coupling portion reaches one side of outer edges of the element regions, the side being located in one direction when viewed from the base. The connecting the terminal includes; applying ultrasonic wave to one end of a wire to bond the one end to the lead frame, a direction of vibration of the ultrasonic wave being parallel to the one direction, and bonding another end of the wire to the terminal. An outer shape of the portion divided into the individual pieces forms an outer shape of the LED package.

Various embodiments will be described hereinafter with reference to the accompanying drawings.

First, a first embodiment will be described.

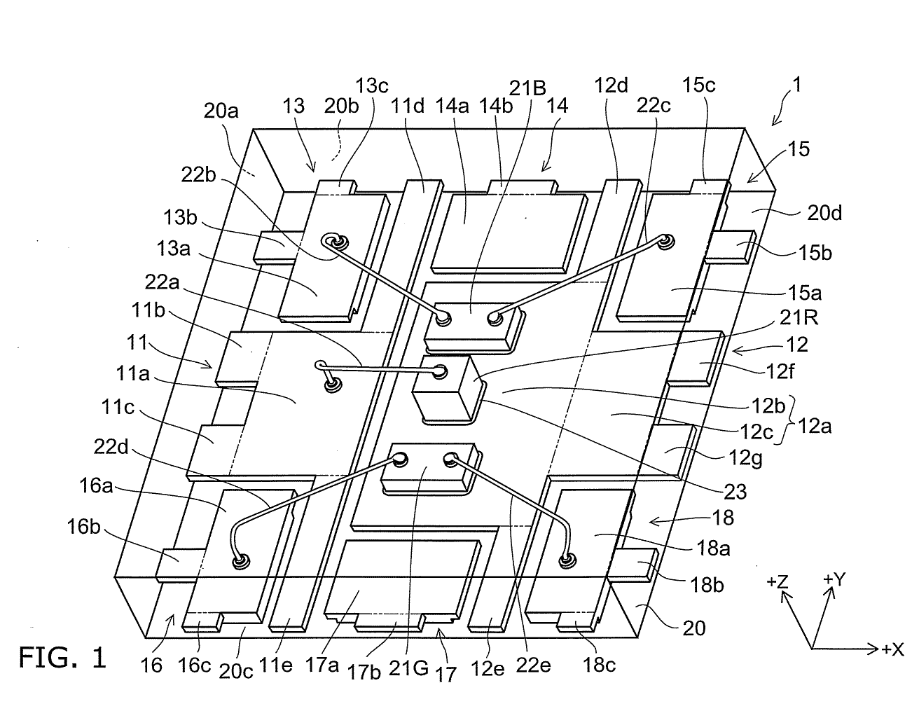

FIG. 1 is a perspective view illustrating an LED package according to the embodiment.

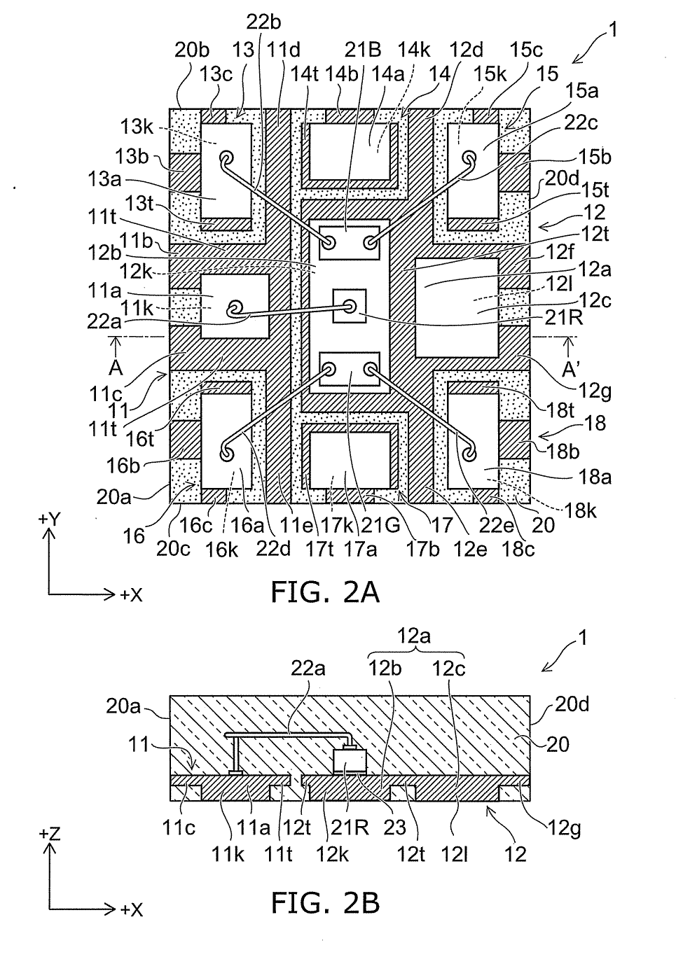

FIG. 2A is a plan view illustrating the LED package according to the embodiment, and FIG. 2B is a cross-sectional view taken along a line A-A′ shown in FIG. 2A.

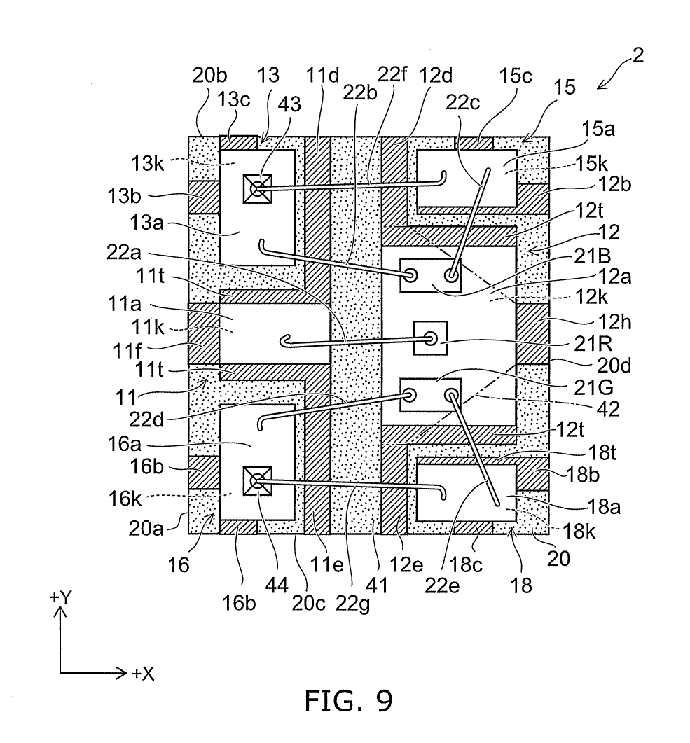

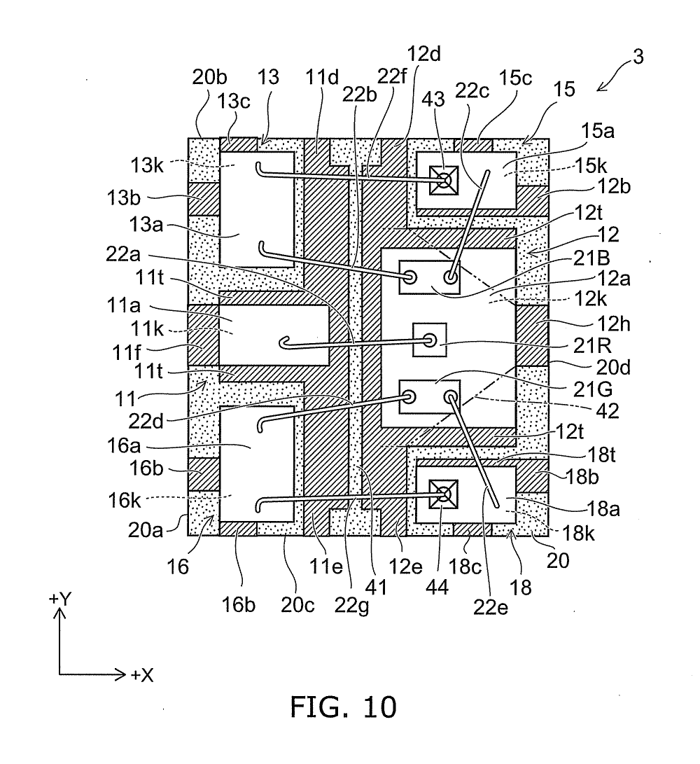

It is to be noted that for convenience of illustration, boundaries between bases and extending portions are shown by chain double-dashed lines in FIG. 1. In addition, thin plate portions are shown marked with oblique lines, and regions with no lead frames are shown marked with dots in FIG. 2A. FIGS. 9 and 10, which will be described hereinafter, are also similar to this.

As shown in FIG. 1, and FIGS. 2A and 2B, eight lead frames 11 to 18 are provided in an LED package 1 according to the embodiment. A shape of the lead frames 11 to 18 is a plate-like one, and they are arranged on a same plane and are separated from one another. The lead frames 11 to 18 are comprised of a same conductive material and, for example, they are configured such that silver plating layers are formed on upper surfaces and lower surfaces of copper plates. It is to be noted that the silver plating layers are not formed on end surfaces of the lead frames 11 to 18, but the copper plates are exposed.

Three LED chips 21R, 21G, and 21B are provided above the lead frames 11 to 18. The LED chip 21R is a vertical conduction type chip that emits red light, the LED chip 21G is a upper surface terminal type chip that emits green light, and the LED chip 21B is the upper surface terminal type chip that emits blue light. In the vertical conduction type chip, one terminal is provided on each of an upper surface and a lower surface thereof. In the upper surface terminal type chip, two terminals are provided on an upper surface thereof.

In addition, in the LED package 1, provided is a transparent resin body 20 with which the respective whole upper surfaces, parts of the lower surfaces, and parts of the end surfaces of the lead frames 11 to 18 are covered, the LED chips 21R, 21G, and 21B are covered, and without which the respective remained portions of the lower surfaces and remained portions of the end surfaces of the lead frames 11 to 18 are exposed. The transparent resin body 20 is formed of transparent resin, for example, silicone resin. It is to be noted that “transparent” also means being translucent. In addition, a hardness of this silicone resin is, for example, Shore D 35 to 50. An outer shape of the transparent resin body 20 is a rectangular parallelepiped, and therefore, a shape thereof is a rectangle when viewed from a Z direction. Additionally, the outer shape of the transparent resin body 20 forms an outer shape of the LED package 1.

Hereinafter, in the specification, an XYZ orthogonal coordinate system will be introduced for convenience of description. Defined to be a +X direction is a direction from the lead frame 11 toward the lead frame 12 among directions parallel to the upper surfaces of the lead frames 11 to 18, defined to be a +Z direction is an upward direction, i.e., a direction from the lead frames toward the LED chips among directions vertical to the upper surfaces of the lead frames 11 to 18, and defined to be a +Y direction is one of directions perpendicular to both the +X direction and the +Z direction. It is to be noted that defined to be a −X direction, a −Y direction, and a −Z direction, respectively are directions opposite to the +X direction, the +Y direction, and the +Z direction. In addition, for example, the “+X direction” and the “−X direction” are collectively simply referred to as an “X direction”.

In the respective lead frames 11 to 18, provided are one base and one or more extending portion(s) extending from the base to the X direction or the Y direction. The base and the extending portion(s) are integrally formed in the each lead frame. The each base is separated from side surfaces 20a to 20d of the transparent resin body 20, and a tip surface of the each extending portion is exposed at the side surfaces 20a to 20d of the transparent resin body 20. In addition, a lower surface of the each base includes a protruding portion, and a portion of the each base where the protruding portion is not formed is a thin plate portion. It is to be noted that a design value of a width of the extending portion is, for example, 0.2 millimeter, and a design value of a thickness thereof is, for example, 0.05 millimeter.

The upper surfaces of the lead frames 11 to 18 constitute parts of a same XY plane. In addition, the extending portions of the lead frames 11 to 18 and lower surfaces of the thin plate portions also constitute parts of another same XY plane. Further, lower surfaces of the protruding portions of the lead frames 11 to 18 also constitute parts of a still another same XY plane. Namely, all the extending portions and the thin plate portions are arranged in a same layer whose upper surface and lower surface are parallel to the XY plane, and a thickness of the extending portions and that of the thin plate portions are the same as each other. Hence, each lead frame has two levels of plate thicknesses. When viewed from the Z direction, a region of the each base where the protruding portion is formed is a thick plate portion where the plate thickness is relatively large, and a region of the base on which the thin plate portion and the extending portion(s) are formed is a thin plate portion where the plate thickness is relatively small.

Additionally, among the lower surfaces of each lead frame, the lower surface of the thick plate portion, i.e., only the lower surface of the protruding portion is exposed at the lower surface of the transparent resin body 20, and the other region of the lower surface of the each lead frame is covered with the transparent resin body 20. Namely, the lower surfaces of the thin plate portions and the extending portions are covered with the transparent resin body 20. In addition, only the tip surfaces of the extending portions among the end surfaces of the each lead frame are exposed at the side surfaces of the transparent resin body 20, and the other region is covered with the transparent resin body 20. Namely, the side surfaces of the bases including the protruding portions, and the side surfaces of the extending portions are covered with the transparent resin body 20. Further, whole regions of the upper surfaces of the lead frames 11 to 18 are covered with the transparent resin body 20. Additionally, the lower surface of the protruding portion of the each lead frame serves as an external electrode pad of the LED package 1. It is to be noted that in the specification, “cover” is a concept including both cases where something to cover with is in contact with something to be covered, and where it is not in contact with it.

Hereinafter, a planar layout of the lead frames 11 to 18 will be described.

As shown in FIG. 1, and FIGS. 2A and 2B, a layout of the lead frames 11 to 18 is symmetrical about an XZ plane that passes through a center of the LED package 1. The lead frame 11 is arranged at a side end of the −X direction in a center of the Y direction of the LED package 1, and the lead frame 12 is arranged from a center of the X direction in the center of the Y direction of the LED package 1 to a side end of the +X direction of the LED package 1. The lead frames 13, 14, and 15 are arranged at a side end of the −X direction, the center of the X direction, and the side end of the +X direction in an end of a +Y direction side of the LED package 1, respectively. The lead frames 16, 17, and 18 are arranged at the side end of the −X direction, the center of the X direction, and the side end of the +X direction in an end of a −Y direction side of the LED package 1, respectively.

The lead frame 11 is provided with a rectangular base 11a when viewed from the Z direction, and four extending portions 11b, 11c, 11d, and lie extend from this base 11a. The extending portions 11b and 11c extend toward the −X direction from the end of the +Y direction side and an end of the −Y direction side of an end edge oriented to the −X direction of the base 11a, respectively, and tip surfaces of the extending portions lib and 11c are exposed at a side surface 20a oriented to the −X direction of the transparent resin body 20. The extending portion 11d extends toward the +Y direction from an end of the +X direction side of an end edge oriented to the Y direction of the base 11a, passes through between the lead frames 13 and 14, and a tip surface of the extending portion 11d is exposed at a side surface 20b oriented to the +Y direction of the transparent resin body 20. The extending portion 11e extends toward the −Y direction from the end of the +X direction side of an end edge oriented to the −Y direction of the base 11a, passes through between the lead frames 16 and 17, and a tip surface of the extending portion 11e is exposed at a side surface 20c oriented to the −Y direction of the transparent resin body 20. Hence, an end edge oriented to the +X direction of the lead frame 11 linearly extends along an entire length of the Y direction of the transparent resin body 20. In addition, a lower surface of the base 11a includes a protruding portion 11k, and a portion of the base 11a where the protruding portion 11k is not formed is a thin plate portion lit. When viewed from the Z direction, a shape of the protruding portion 11k is a rectangle, and a shape of the thin plate portion 11t is a U-shaped one open to the −X direction.

The lead frame 12 is provided with a protrusion-shaped base 12a oriented to the +X direction when viewed from the Z direction. Namely, the base 12a is provided with: a rectangular portion 12b whose length in the Y direction is longer than that of the base 11a of the lead frame 11, the portion being arranged in a region including the center of the LED package 1 when viewed from the Z direction; and a rectangular portion 12c whose length in the Y direction is equal to that of the base 11a of the lead frame 11, the portion being arranged at the +X direction side of the rectangular portion 12b, and being continuous with the rectangular portion 12b.

A extending portion 12d extends toward the +Y direction from the end of the +X direction side of an end edge oriented to the +Y direction of the rectangular portion 12b, passes through between the lead frames 14 and 15, and a tip surface of the extending portion 12d is exposed at the side surface 20b oriented to the +Y direction of the transparent resin body 20. A extending +X portion 12e extends toward the −Y direction from the end of the +X direction side of an end edge oriented to the −Y direction of the rectangular portion 12b, passes through between the lead frames 17 and 18, and a tip surface of the extending portions 12e is exposed at the side surface 20c oriented to the −Y direction of the transparent resin body 20. Extending portions 12f and 12g extend toward the +X direction respectively from the end of the +Y direction side and the end of the −Y direction side of an end edge oriented to the +X direction of the rectangular portion 12c, and tip surfaces of the extending portions 12f and 12g are exposed at a side surface 20d oriented to the +X direction of the transparent resin body 20. In addition, lower surfaces of the rectangular portions 12b and 12c include protruding portions 12k and 12l, respectively. When viewed from the Z direction, shapes of the protruding portions 12k and 12l are rectangles, respectively. A portion of the base 12a where the protruding portions 12k and 12l are not formed is a thin plate portion 12t.

The lead frame 13 is provided with one base 13a, and two extending portions 13b and 13c extend from this base 13a. When viewed from the Z direction, a shape of the base 13a is a rectangle in which the Y direction corresponds to a longitudinal direction. The extending portion 13b extends toward the −X direction from a center of the Y direction of an end edge oriented to the −X direction of the base 13a, and a tip surface of the extending portion 13b is exposed at the side surface 20a of the transparent resin body 20. The extending portion 13c extends toward the +Y direction from a portion of the −X direction side of an end edge oriented to the +Y direction of the base 13a, and a tip surface of the extending portion 13c is exposed at the side surface 20b of the transparent resin body 20. A lower surface of the base 13a excluding an end of the −Y direction side includes a protruding portion 13k, and a portion of the base 13a where the protruding portion 13k is not formed, i.e., the end of the −Y direction side is a thin plate portion 13t. When viewed from the Z direction, shapes of the protruding portion 13k and a thin plate portion 13t are rectangles, respectively.

The lead frame 14 is provided with a rectangular base 14a when viewed from the Z direction, and one extending portion 14b extends from this base 14a. The extending portion 14b extends toward the +Y direction from a center of the X direction of an end surface oriented to the +Y direction of the base 14a, and a tip surface of the extending portion 14b is exposed at the side surface 20b of the transparent resin body 20. In addition, a lower surface of a portion in contact with the extending portion 14b of the base 14a includes a protruding portion 14k. A portion of the base 14a where the protruding portion 14k is not formed is a thin plate portion 14t. When viewed from the Z direction, a shape of the protruding portion 14k is a rectangle, and a shape of the thin plate portion 14t is a U-shaped one open to the +Y direction.

A shape of the lead frame 15 is a mirror image of the lead frame 13 with respect to an YZ plane that passes through the center of the LED package 1. Namely, the lead frame 15 is provided with a base 15a and two extending portions 15b and 15c, and tip surfaces of the extending portions 15b and 15c are exposed at the side surfaces 20d and 20b, respectively.

A layout of the lead frames 16, 17, and 18 is a mirror image of the lead frames 13, 14, and 15 with respect to the XZ plane that passes through the center of the LED package 1.

The above-described LED chips 21R, 21G, and 21B are mounted on the rectangular portion 12b of the base 12a of the lead frame 12, and they are arranged in a region above the protruding portion 12k. The LED chips 21R, 21G, and 21B are aligned in a line along the Y direction separated from one another, the LED chip 21R is arranged in a center of the line, the LED chip 21B is at the +Y direction side thereof, and the LED chip 21G is at the −Y direction side thereof. When viewed from the Z direction, the LED chip 21R is arranged nearly in the center of the LED package 1.

An upper surface terminal of the LED chip 21R is connected to the lead frame 11 through a wire 22a, and a lower surface terminal thereof is connected to the lead frame 12 through a conductive die mount material 23. Pairs of upper surface terminals provided at the LED chips 21B and 21G, respectively are aligned along the X direction. One terminal provided on an upper surface of the LED chip 21B is connected to the lead frame 13 through a wire 22b, and the other terminal thereof is connected to the lead frame 15 through a wire 22c. One terminal provided on an upper surface of the LED chip 21G is connected to the lead frame 16 through a wire 22d, and the other terminal thereof is connected to the lead frame 18 through a wire 22e. It is to be noted that the die mount material 23 is, for example, formed of silver paste or solder, and the wires 22a to 22e are, for example, formed of gold or aluminum.

As for the wires 22a to 22e (hereinafter collectively also referred to as a “wire 22”), an angle between a direction to which the wire 22 is pulled out from an end joined to the terminal of the LED chip and the XY plane (hereinafter referred to as a “chip side pull-out angle”) is smaller than an angle between a direction to which the wire 22 is pulled out from an end joined to the lead frame and the XY plane (hereinafter referred to as a “frame side pull-out angle”). For example, the chip side pull-out angle is 0 to 5 degree(s), and the frame side pull-out angle is 85 to 90 degrees. In addition, a portion other than both ends of the wire 22 is displaced toward the center of the LED package 1 when viewed from a region directly above a straight line connecting these both ends. Specifically, portions other than both ends of the wires 22b and 22c connected to the LED chip 21B are located at the −Y direction side when viewed from straight lines connecting these both ends. In addition, portions other than both ends of the wires 22d and 22e connected to the LED chip 21G are located at the +Y direction side when viewed from straight lines connecting these both ends.

As described above, on the each of the eight lead frames 11 to 18, provided is/are one or more extending portion(s) whose tip surface(s) is/are exposed at the side surface 20b or 20c of the transparent resin body 20, the extending portion(s) extending in the Y direction. In addition, on each of the six lead frames 11, 12, 13, 15, 16, and 18 to which any of the terminals of the LED chips 21R, 21B, and 21G has been connected, provided is/are one or more extending portion(s) whose tip surface(s) is/are exposed at the side surface 20a or 20d of the transparent resin body 20, the extending portion(s) extending in the X direction. Hence, on the six lead frames to which the terminals of the LED chips have been connected, provided is a plurality of extending portions whose tip surfaces are exposed at the two side surfaces perpendicular to each other of the transparent resin body 20. Particularly, the tip surfaces of the extending portions 12d to 12g of the lead frame 12 on which the three LED chips 21R, 21B, and 21G are mounted are exposed at the three side surfaces 20b, 20c, and 20d different from one another of the transparent resin body 20.

Next will be described a method for manufacturing the LED package according to the embodiment.

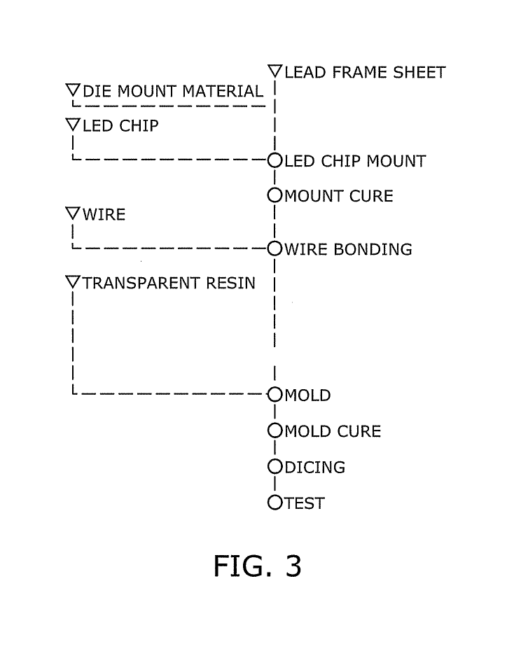

FIG. 3 is a flow chart illustrating the method for manufacturing the LED package according to the embodiment.

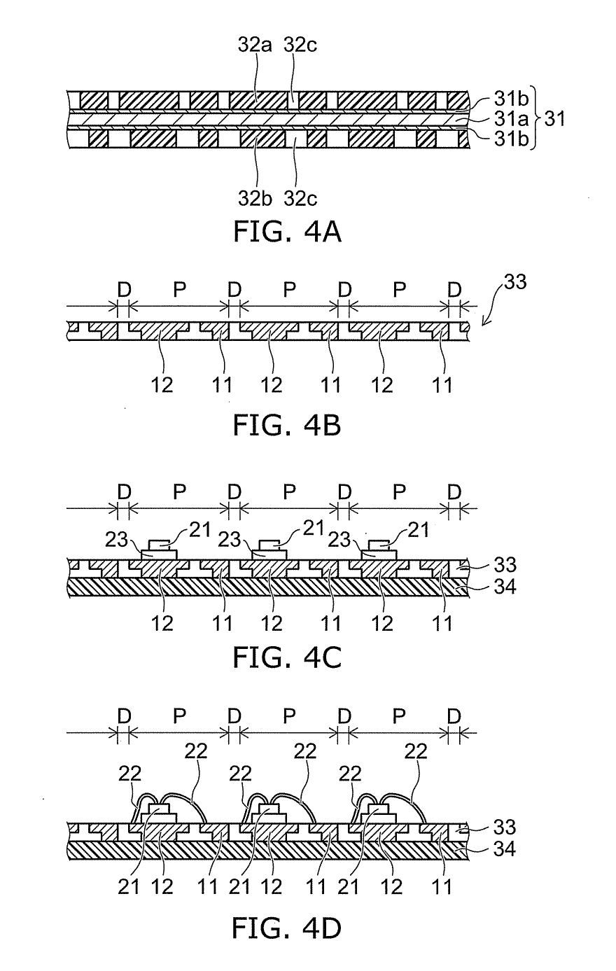

FIGS. 4A to 4D, FIGS. 5A to 5C, and FIGS. 6A and 6B are cross-sectional views of processes illustrating the method for manufacturing the LED package according to the embodiment.

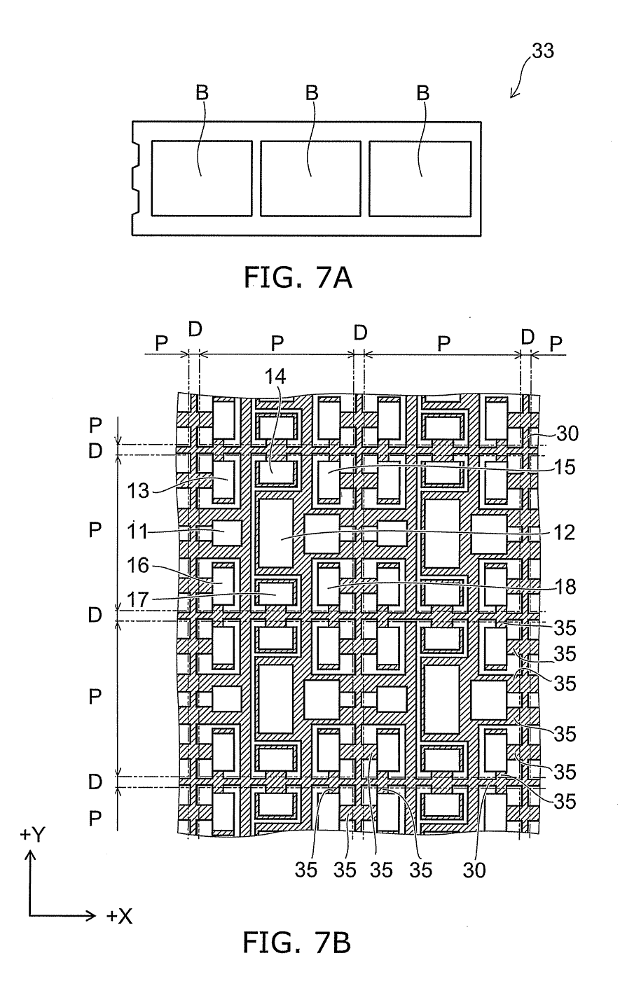

FIG. 7A is a plan view illustrating a lead frame sheet in the embodiment, and FIG. 7B is a partial enlarged plan view illustrating an element region of this lead frame sheet.

It is to be noted that a structure of the each LED package is simply depicted for convenience of illustration in FIGS. 4A to 4D to FIGS. 7A and 7B. For example, LED chips are collectively referred to as an LED chip 21, and wires are collectively referred to as a wire 22. In addition, thin plate portions are shown marked with oblique lines in FIG. 7B.

First, as shown in FIG. 4A, a conductive sheet 31 comprised of a conductive material is prepared. This conductive sheet 31 is, for example, formed by applying silver plating layers 31b to top and lower surfaces of a strip-shaped copper plate 31a. Next, masks 32a and 32b are formed on top and lower surfaces of this conductive sheet 31. Openings 32c are selectively formed on the masks 32a and 32b. The masks 32a and 32b can be formed, for example, by a printing method.

Next, the conductive sheet 31 is wet-etched by immersing in an etchant the conductive sheet 31 on which the masks 32a and 32b are deposited. As a result of this, portions located inside the openings 32c of the conductive sheet 31, are etched to be selectively removed. At this time, for example, an etching amount is controlled by adjusting an immersing time, and etching is stopped before the etching from an upper surface side and a lower surface side of the conductive sheet 31 respectively independently penetrates the conductive sheet 31. As a result of this, half etching is performed from the top and lower surfaces side. However, portions etched from both the upper surface side and the lower surface side are made to penetrate the conductive sheet 31. Subsequently, the masks 32a and 32b are removed.

As a result of this, as shown in FIGS. 3 and 4B, the copper plate 31a and the silver plating layers 31b are selectively removed from the conductive sheet 31, and then a lead frame sheet 33 is formed. It is to be noted that for convenience of illustration, the copper plate 31a and the silver plating layers 31b are not distinguished from each other, but they are integrally depicted as the lead frame sheet 33 in the drawings subsequent to FIG. 4B.

As shown in FIG. 7A, for example, three blocks B are set on the lead frame sheet 33, and for example, approximately 1000 element regions P are set in the each block B. In addition, target marks (not shown) used for alignment in a latter process are formed on the lead frame sheet 33. More specifically, macro targets are formed at corners of the block B. In addition, a micro target is formed in each element region P along an outer edge of the block B.

As shown in FIG. 7B, the element regions P are aligned in a matrix form, and spaces between the element regions P are lattice-shaped dicing regions D. The conductive material forming the conductive sheet 31 is completely removed from regions etched from both the upper surface side and the lower surface side of the lead frame sheet 33, and the regions become penetration regions. In addition, only a under portion of the conductive sheet 31 is removed from regions etched only from the lower surface side of the lead frame sheet 33, and the regions become thin plate portions. Further, the conductive sheet 31 completely remains in regions etched from neither the upper surface side nor the lower surface side of the lead frame sheet 33, and the regions become thick plate portions. In a manner described above, a basic pattern including the eight lead frames 11 to 18 separated from one another is formed in the each element region P. In addition, lattice-shaped support members 30 are formed in the dicing regions D.

Each lead frame is provided with: a base separated from an outer edge of the element region P; and a coupling portion 35 that extends from the base, reaches the outer edge of the element region P, and is coupled with the support member 30. Particularly, the six lead frames 11, 12, 13, 15, 16, and 18 connected to the LED chips in a latter process are respectively provided with a plurality of coupling portions 35, some coupling portions 35 extend in the X direction to reach a side extending in the Y direction of the outer edge of the element region P, and the remaining coupling portions 35 extend in the Y direction to reach a side extending in the X direction of the outer edge of the element region P. Namely, the plurality of coupling portions 35 provided on the six lead frames connected to the LED chips have reached the two sides perpendicular to each other of the outer edge of the element region P. In addition, a design value of a distance between the coupling portions 35 is set to be not less than 0.3 millimeter.

Next, as shown in FIGS. 3 and 4C, a reinforcing tape 34 formed of, for example, polyimide, is applied on the lower surface of the lead frame sheet 33. The die mount material 23 is then deposited on the lead frame belonging to the each element region P of the lead frame sheet 33. Next, the LED chips 21R, 21G, and 21B are mounted on the die mount materials 23. Next, heat treatment (mount cure) for sintering the die mount materials 23 is performed. As a result of this, the LED chips 21R, 21G, and 21B are mounted on the lead frames through the die mount materials 23 in the respective element regions P of the lead frame sheet 33.

Next, as shown in FIGS. 3 and 4D, one end of the wire 22 is joined to the upper surface of the each lead frame by, for example, ultrasonic joining. Subsequently, the wire 22 is pulled out from this joining portion nearly to an upper side (+Z direction), bent nearly to a right angle, and nearly horizontally pulled out to an upper side of the each LED chip 21. The other end of the wire 22 is then joined to the terminal of the each LED chip 21. A vibration direction of ultrasonic waves is defined to be the Y direction in the above-described ultrasonic joining. As a result of this, each terminal provided on the upper surface of the each LED chip is connected to the each lead frame through the wire 22.

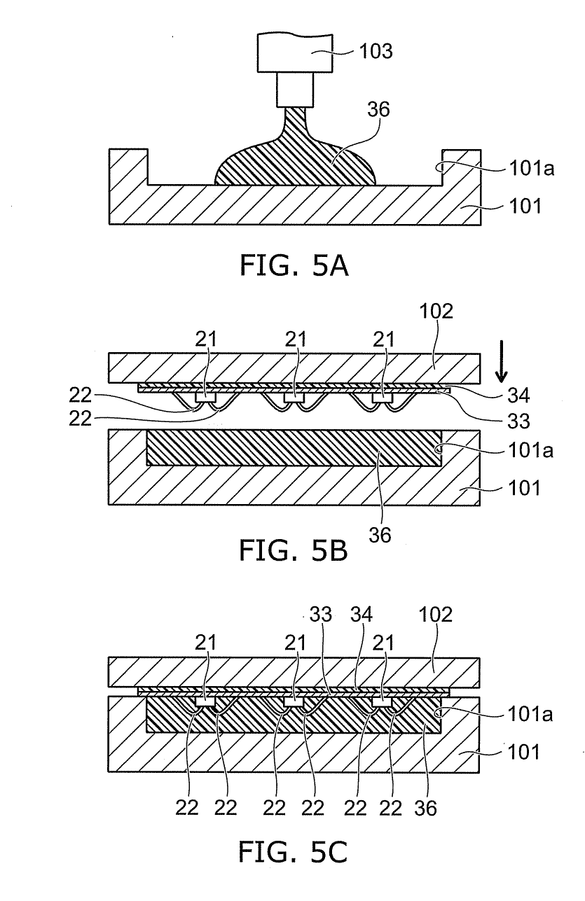

Next, as shown in FIGS. 3 and 5A, a lower mold 101 is prepared. The lower mold 101 constitutes a pair of molds together with an upper mold 102 that will be described hereinafter, and a rectangular-parallelepiped-shaped concave portion 101a is formed on an upper surface of the lower mold 101. Meanwhile, a liquid or a semi-liquid resin material 36 is prepared with transparent resin, such as silicone. It is to be noted that at this time, a diffusing agent may be added to the resin material 36. The resin material 36 is then supplied in the concave portion 101a of the lower mold 101 by a dispenser 103.

Next, as shown in FIGS. 3 and 5B, the lead frame sheet 33 having the above-described LED chips 21 mounted thereon is attached on a lower surface of the upper mold 102 so that the LED chips 21 may be oriented downwardly. Subsequently, as shown in FIG. 5C, the upper mold 102 is pressed against the lower mold 101, and the mold is clamped. As a result of this, the lead frame sheet 33 is pressed against the resin material 36. At this time, the resin material 36 covers the LED chips 21 and the wires 22, and also wraps around into the portions of the lead frame sheet 33 removed by etching. In a manner described above, the resin material 36 is molded. This molding process is preferably carried out in a vacuum atmosphere. As a result of this, bubbles generated in the resin material 36 can be prevented from adhering to the half-etched portions of the lead frame sheet 33. Next, heat treatment (mold cure) is performed in a state where the upper surface of the lead frame sheet 33 is pressed on the resin material 36, and the resin material 36 is cured.

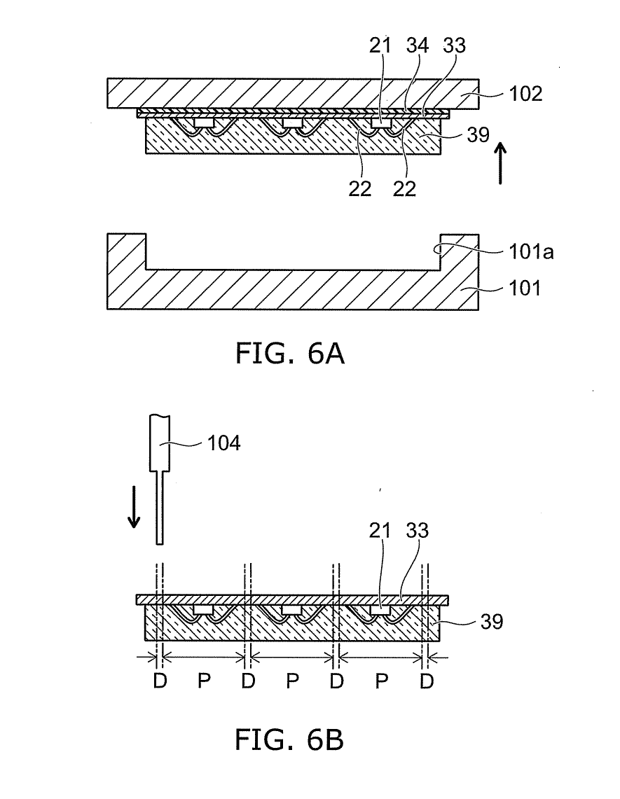

Next, as shown in FIG. 6A, the upper mold 102 is pulled apart from the lower mold 101. As a result of this, formed is at least a transparent resin plate 39 that covers the LED chips 21, the upper surface of the lead frame sheet 33, and lower surfaces of the coupling portions 35. Subsequently, the reinforcing tape 34 is torn off from the lead frame sheet 33. As a result of this, lower surfaces of the protruding portions of the lead frames are exposed at a surface of the transparent resin plate 39.

Next, as shown in FIGS. 3 and 6B, a combined body comprised of the lead frame sheet 33 and the transparent resin plate 39 is diced from a lead frame sheet 33 side by a blade 104. Namely, it is diced toward the +Z direction. As a result of this, portions arranged in the dicing regions D of the lead frame sheet 33 and the transparent resin plate 39 are removed. Consequently, portions arranged in the element regions P of the lead frame sheet 33 and the transparent resin plate 39 are made into individual pieces, and thereby LED packages are manufactured. It is to be noted that the combined body comprised of the lead frame sheet 33 and the transparent resin plate 39 may be diced from a transparent resin plate 39 side.

In the each LED package after dicing, the respective lead frames 11 to 18 are separated from one another from the lead frame sheet 33. In addition, the transparent resin plate 39 is divided to be the transparent resin body 20. At this time, the support member 30 and portions of a support member 30 side in the each coupling portion 35 are removed, and a remained portion of the coupling portion 35 serves as the extending portion. Additionally, a cut plane of the coupling portion 35, i.e., the tip surface of the each extending portion, is exposed at a side surface of the transparent resin body 20.

Next, as shown in FIG. 3, various kinds of tests are performed with respect to the LED packages. At this time, it is also possible to use the tip surfaces of the extending portions as terminals for the tests.

Next, effects of the embodiment will be described.

A large number of, for example, approximately thousands of LED packages can be collectively manufactured from one conductive sheet 31 in the embodiment. As a result of this, manufacturing cost per one LED package can be reduced. In addition, many parts and processes are not needed since no envelope is provided, thus resulting in low cost.

In addition, the lead frame sheet 33 is formed by wet etching in the embodiment. Hence, when manufacturing an LED package with a new layout, it is only necessary to prepare an original of the mask, and initial cost can be suppressed to be lower as compared with a case where the lead frame sheet 33 is formed by a method, such as press by a mold.

Further, the coupling portions 35 extend from the base of the each lead frame in the lead frame sheet 33 in the embodiment. As a result of this, the lead frame 12 is supported by the support member 30 in a mounting process of the LED chips 21 shown in FIG. 4C, and therefore, mountability is high. Similarly, since joining positions of the wires 22 are supported also in a wire bonding process shown in FIG. 4D, for example, ultrasonic waves applied at the time of ultrasonic joining rarely escape, and the wires 22 can be successfully joined to the lead frames and the LED chips 21.

Particularly, in the six lead frames 11, 12, 13, 15, 16, and 18 to which the wires 22 are joined, provided are the coupling portions 35 that extend from the bases to the Y direction, which is a vibration direction of the ultrasonic waves, and that reach a side located in the Y direction when viewed from the bases in the outer edge of the element region P (refer to FIG. 7B) to be coupled to the support members 30. As a result of this, these lead frames are supported from the Y direction by the support member 30. Hence, these coupling portions 35 serve as reinforcing bars to thereby effectively suppress vibration of the lead frames accompanied with applying of the ultrasonic waves, thus enabling to effectively apply the ultrasonic waves to the joining portions of the wires and the lead frames.

In addition, the six lead frames to which the wires are joined are provided with the coupling portions 35 extending in the X direction and the coupling portions 35 extending in the Y direction. As a result of this, the lead frames are supported from both the X direction and the Y direction by the support members 30, and thus even though the vibration direction of the ultrasonic waves is any direction in the XY plane, vibration of the lead frame can be suppressed effectively, and the ultrasonic waves can be applied efficiently. Hence, it is not necessary to manage the vibration direction of the ultrasonic waves at the time of wire bonding. Consequently, manufacturing cost of the LED package 1 can be reduced.

Further, the extending portions of the lead frame 12 on which the three LED chips 21R, 21G, and 21B are mounted are exposed at the three side surfaces 20b, 20c, and 20d different from one another of the transparent resin body 20. As a result of this, the lead frame 12 can be supported from three directions, and therefore, mountability of the LED chips 21 and wire bonding capability with respect to the terminals of the LED chips 21 are further improved.

Still further, the design value of the distance between the coupling portions 35 is set to be not less than 0.3 millimeter in the embodiment. As a result of this, short between the extending portions can be reliably prevented in the manufactured LED package 1. If there is no error in the processes when manufacturing the LED package 1, an actual measurement value of the distance between the extending portions becomes equal to the design value of the distance between the coupling portions 35. However, actually, many errors in the processes are caused, and thereby an actual measurement value of the distance between the extending portions after manufacturing the LED package 1 varies within a certain range with respect to the design value of the distance between the coupling portions 35. Major ones of the errors in the processes include the following (1) to (6).

(1) A position deviation between the micro targets and the support members 30 in the lead frame sheet 33

(2) A tolerance of widths of the support members 30

(3) A tolerance of widths of the coupling portions 35 (extending portions)

(4) A tolerance of positions of the coupling portions 35 (extending portions)

(5) Round corners formed at intersections by etching

(6) Accuracy of a dicing apparatus

In addition, process capability when manufacturing the LED package 1 also depends on a width of the blade 104 (refer to FIG. 6B) used for dicing. When an change amount of the width of the extending portion before and after dicing was considered as 3σ per one side, a distance between the extending portions with which the extending portions did not short with one another, but could ensure the process capability Cpk to be not less than 1.33, i.e., a minimum value of the design value of the distance between the coupling portions 35, was 230 micrometers when a blade of 200 micrometers width was used, and was 350 micrometers when a blade of 150 micrometers width was used. Hence, the design value of the distance between the extending portions is set to be not less than a predetermined value according to the width of the blade, and thereby reduction in size of the LED package 1 can be achieved while preventing short and ensuring the yield. As a result of this, it becomes possible to further reduce cost of the LED package 1.

Still further, the lead frames 14 and 17 to which the LED chips 21 are not connected are provided in the embodiment. As a result of this, when viewed from the Z direction, the lead frames are arranged nearly in a whole region in the transparent resin body 20. Hence, most of the light emitted downwardly from the LED chips 21 is reflected by the lead frames to proceed upwardly. Consequently, light extraction efficiency can be enhanced. Particularly, silver plating layers are formed on the upper surfaces and the lower surfaces of the lead frames in the LED package 1 according to the embodiment. Since a light reflectance of the silver plating layer is high, the LED package 1 according to the embodiment has a high light extraction efficiency.

Still further, the chip side pull-out angle of the wire 22 is smaller than the frame side pull-out angle thereof in the embodiment. As a result of this, a loop of the wire 22 can be formed lower, and thereby a height of the transparent resin body 20 can be reduced. Consequently, a thermal expansion amount and thermal stress of the transparent resin body 20 can be reduced, and thereby fracture of joining portions of the wire 22 due to the thermal stress received from the transparent resin body 20 can be prevented.

Still further, when the transparent resin body 20 expands with heat, thermal stress toward a peripheral upper portion of the transparent resin body 20 acts on the wire 22, and when the transparent resin body 20 contracts with heat, thermal stress toward a central lower portion of the transparent resin body 20 acts on the wire 22. In the embodiment, the portion other than the both ends of the wire 22 is displaced toward the center of the LED package 1 when viewed from the region directly above the straight line connecting these both ends. Hence, when thermal expansion and thermal contraction of the transparent resin body 20 occur, the wire 22 is deformed nearly into a state where it was rotationally moved with the both ends thereof being axes was performed, and therefore it is not easily fractured. In contrast with this, if the portion other than the both ends of the wire 22 is displaced in a direction to move away from the center of the LED package 1, when thermal expansion and thermal contraction of the transparent resin body 20 occur, the wire 22 is deformed nearly into a state where motion of crushing or drawing out the loop thereof was performed, and therefore the wire is easily fractured.

Still further, the transparent resin body 20 covers the thin plate portions of the lead frames 11 to 18, i.e., the thin plate portions and the lower surfaces of the extending portions, and thereby peripheries of the lead frames are held in the embodiment. Hence, holding performance for the lead frames can be enhanced while exposing the lower surfaces of the protruding portions of the lead frames from the transparent resin body 20 to achieve an external electrode pad. As a result of this, the lead frames 11 to 18 become difficult to be peeled off from the transparent resin body 20 at the time of dicing, thus enabling to improve the yield of the LED package 1. In addition, peeling-off of the lead frames 11 to 18 from the transparent resin body 20 due to temperature stress can be prevented at the time of using the LED package 1.

Still further, the extending portions extend from the bases of the respective lead frames, respectively in the embodiment. As a result of this, the bases themselves are not exposed at the side surfaces of the transparent resin body 20, thus enabling to reduce an exposure area of the lead frames. In addition, a contact area of the lead frames 11 to 18 and the transparent resin body 20 can be increased. Consequently, peeling-off of the lead frames from the transparent resin body 20 can be prevented. In addition, corrosion of the lead frames can also be suppressed.

Still further, the LED chips 21R, 21G, and 21B are arranged in a region above the protruding portion 12k of the lead frame 12 in the embodiment. Since a lower surface of the protruding portion 12k is exposed from the lower surface of the transparent resin body 20 to be connected to an external wire etc., heat generated in the each LED chip 21 flows through the lead frame 12 to a directly downward direction (−Z direction) to be emitted outside. Consequently, the LED package 1 according to the embodiment has excellent heat radiation performance.

Next, a variation of the embodiment will be described.

The variation is the one of a method for forming a lead frame sheet.

Namely, in the variation, a method for forming the lead frame sheet shown in FIGS. 7A and 7B is different from that of the above-described first embodiment.

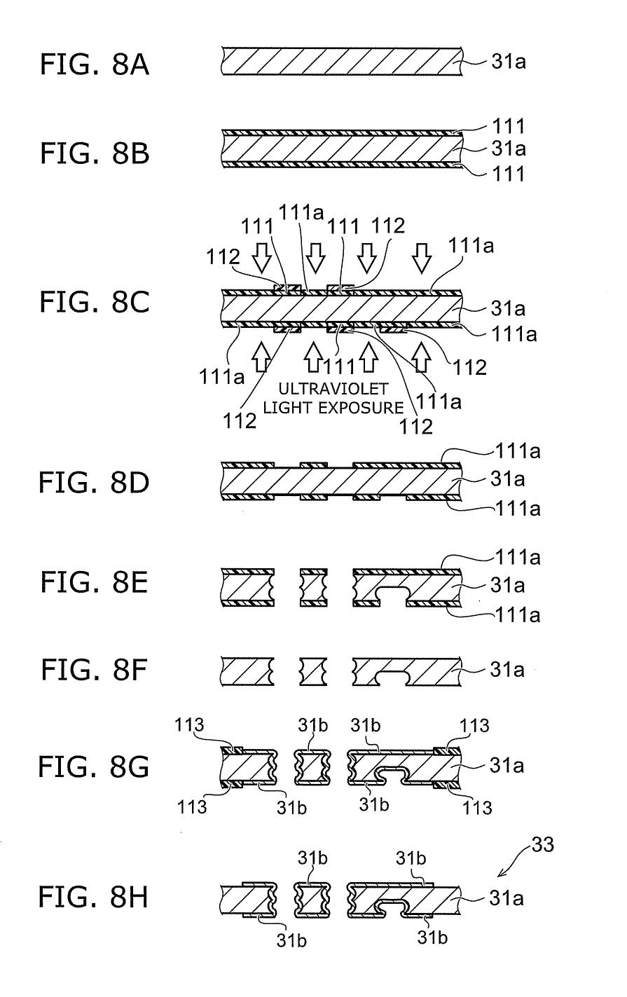

FIGS. 8A to 8H are cross-sectional views of processes illustrating the method for forming the lead frame sheet in the variation.

First, as shown in FIG. 8A, the copper plate 31a is prepared to be cleaned. Next, as shown in FIG. 8B, resist is coated onto both surfaces of the copper plate 31a, and subsequently, dried it to form resist films 111. Next, as shown in FIG. 8C, mask patterns 112 are arranged on the resist films 111, and they are irradiated with ultraviolet rays to be exposed. As a result of this, exposed portions of the resist films 111 are cured, and thereby resist masks 111a are formed. Next, as shown in FIG. 8D, development is performed, and uncured portions of the resist films 111 are flushed. As a result of this, the resist patterns 111a remain on a top and a lower surfaces of the copper plate 31a. Next, as shown in FIG. 8E, etching is performed using the resist patterns 111a as masks, and the exposed portions of the copper plate 31a are removed from the both surfaces thereof. At this time, an etched depth is set to be about a half of a plate thickness of the copper plate 31a. As a result of this, regions etched only from one surface side are half-etched, and regions etched from both surface sides are penetrated. Next, as shown in FIG. 8F, the resist patterns 111a are removed. Next, as shown in FIG. 8G, ends of the copper plate 31a are covered with masks 113, and then the copper plate 31a is plated. As a result of this, silver plating layers 31b are formed on surfaces of portions other than the ends of the copper plate 31a. Next, as shown in FIG. 8H, the masks 113 are removed by cleaning. Subsequently, inspections are performed. In a manner described above, the lead frame sheet 33 is fabricated. Configurations, manufacturing methods, and effects other than the above in the variation are similar to those of the above-described first embodiment.

Next, a second embodiment will be described.

FIG. 9 is a plan view illustrating an LED package according to the embodiment.

As shown in FIG. 9, as compared with the above-described LED package 1 according to the first embodiment (refer to FIGS. 1 and 2), the LED package 2 according to the embodiment is different in the layout of the lead frames and different in that Zener diode chips are provided therein.

Hereinafter, differences with the LED package 1 in the LED package 2 will be described.

The LED package 2 is different in that the lead frames 14 and 17 are not provided therein as compared with the LED package 1. Namely, the six lead frames 11, 12, 13, 15, 16, and 18 are provided in the LED package 2. In addition, in the LED package 2, a layout of the lead frames 13 and 15 is not symmetrical about the YZ plane, and a layout of the lead frames 16 and 18 is not symmetrical about the YZ plane, either.

In the lead frame 11, a length of the base 11a in the Y direction is shorter as compared with the LED package 1. In addition, an area of the protruding portion ilk is larger, the shape of the thin plate portion lit is not the U-shaped one, but it is two belt-like ones extending in the X direction. Further, one extending portion 11f is provided with the lead frame 11 instead of the two extending portions lib and 11c in the LED package 1. The extending portion 11f extends from the base 11a to the −X direction, and a width thereof is equal to that of the protruding portion 11k. It is to be noted that similarly to the first embodiment, the end edge oriented to the +X direction of the lead frame 11 linearly extends along the entire length of the Y direction of the transparent resin body 20.

In the lead frame 12, the base 12a is not divided into the rectangular portions 12b and 12c (refer to FIG. 2), but it is a single rectangular-shaped portion. In addition, an end edge of the −X direction side of the lead frame 12 retreats to the +X direction side as compared with the first embodiment. Further, the protruding portion 12k is provided along an entire length of the X direction of the base 12a, and the thin plate portion 12t is provided only both ends of the Y direction of the base 12. Still further, extending portions 12d and 12e extend toward the +Y direction and the −Y direction from ends of the −X direction side of the base 12, respectively. Hence, an end edge oriented to the −X direction of the lead frame 12 linearly extends along the entire length of the Y direction of the transparent resin body 20. Still further, one extending portion 12h is provided with the lead frame 12 instead of the two extending portions 12f and 12g in the LED package 1. The extending portion 12h extends toward the +X direction from a center of the Y direction in an end edge oriented to the +X direction of the base 12a, and a width thereof is equal to that of the extending portion 11f.

As described above, the end edge oriented to the +X direction of the lead frame 11 linearly extends along the entire length of the Y direction of the transparent resin body 20, and the end edge oriented to the −X direction of the lead frame 12 also linearly extends along the entire length of the Y direction of the transparent resin body 20. Hence, these end edges, i.e., the end edges opposed to each other in the lead frames 11 and 12, are parallel to each other, and a belt-like region 41 on which no lead frame is arranged is formed between the lead frames 11 and 12.

In addition, the LED chips 21R, 21G, and 21B are arranged closer to the +X direction side than a center of the LED package 2. When viewed from the Z direction, the respective terminals of the LED chips 21R, 21G, and 21B are arranged inside a virtual polygonal area 42 formed by connecting roots of the extending portions 12d, 12e, and 12h. An n type layer (not shown) is formed in a lower portion of the LED chip 21R, and a p type layer (not shown) is formed in an upper portion of the LED chip 21R. Thus, the LED chip 21R passes current to the lower surface terminal from the upper surface terminal thereof, that is, to the lead frame 12 from the lead frame 11.

In the lead frame 13, a length of the X direction of the base 13a is longer as compared with the LED package 1, and the whole base 13a includes the protruding portion 13k. Namely, the thin plate portion 13t (refer to FIG. 2) is not provided on the lead frame 13 in the embodiment.

In the lead frame 15, a shape of the base 15a is a rectangle in which the X direction corresponds to a longitudinal direction. In addition, the extending portion 15b extends toward the +X direction from an end of the −Y direction side in an end edge oriented to the +X direction of the base 15a, and a root of the extending portion 15b is coupled to a thin plate portion 15t. The extending portion 15c extends toward the +Y direction from a center of the X direction in an end edge oriented to the +Y direction of the base 15a.

A layout of the lead frames 16 and 18 is a mirror image of the lead frames 13 and 15 with respect to the XZ plane that passes through the center of the LED package 2.

In addition, vertical conduction type Zener diode chips 43 and 44 are provided in the LED package 2 according to the embodiment. The Zener diode chip 43 is mounted on the base 13a of the lead frame 13, a lower surface terminal thereof is connected to the lead frame 13 through a conductive die mount material (not shown), and a upper surface terminal thereof is connected to the base 15a of the lead frame 15 through a wire 22f. As a result of this, the Zener diode chip 43 is connected in parallel to the LED chip 21B. In addition, the Zener diode chip 44 is mounted on a base 16a of the lead frame 16, a lower surface terminal thereof is connected to the lead frame 16 through the conductive die mount material (not shown), and a upper surface terminal thereof is connected to a base 18a of the lead frame 18 through a wire 22g. As a result of this, the Zener diode chip 44 is connected in parallel to the LED chip 21G.

Next, effects of the embodiment will be described.

In the embodiment, a fewer number of extending portions are used as compared with the above-described first embodiment. Namely, while tip surfaces of a total of 18 extending portions are exposed at the side surfaces 20a to 20d of the transparent resin body 20 in the LED package 1 (refer to FIGS. 1 and 2) according to the first embodiment, tip surfaces of a total of 14 extending portions are exposed at the side surfaces 20a to 20d in the LED package 2 (refer to FIG. 9) according to the embodiment. Hence, in the embodiment, distances between the extending portions can be relatively larger as compared with the above-described first embodiment. As a result of this, reduction in size of the LED package 2 can be achieved while maintaining the distances between the extending portions to be not less than a certain value to thereby prevent short.

In addition, in the embodiment, when viewed from the Z direction, the respective terminals of the LED chips 21R, 21G, and 21B are arranged inside the virtual polygonal area 42 formed by connecting the roots of the extending portions 12d, 12e, and 12h. As a result of this, when joining the wires 22 to these terminals, the LED chips can be held more firmly. Consequently, ultrasonic waves can be applied more efficiently, and wire bonding capability is further improved.

Further, since vertical conduction type Zener diode chips 43 and 44 are provided in the LED package 2 according to the embodiment, a tolerance for ESD (Electrostatic Discharge) is higher as compared with the above-described LED package 1 according to the first embodiment. Configurations, manufacturing methods, operations, and effects other than the above in the embodiment are similar to those of the above-described first embodiment.

Next, a third embodiment will be described.

FIG. 10 is a plan view illustrating an LED package according to the embodiment.

As shown in FIG. 10, an LED package 3 according to the embodiment is different in the layout of the lead frames and arrangement of the Zener diode chips as compared with the above-described LED package 2 (refer to FIG. 9) according to the second embodiment.

Namely, in the LED package 3 according to the embodiment as shown in FIG. 10, a portion of the edge on the +X direction side of the lead frame 11 other than both ends thereof extends to the +X direction, and a portion of the edge on the −X direction side of the lead frame 12 other than both ends thereof extends to the −X direction. Note that, the lead frames 11 and 12 are not contact with each other. Therefore, in the LED package 3, a portion of the belt-like region 41 other than both ends thereof is narrower than the both ends of the belt-like region 41.

In this way, the lead frames 11 and 12 expose at the side surfaces 20b and 20c of the transparent resin body 20. And a distance between the lead frame 20b and the lead frame 20c in the transparent resin body 20 is shorter than a distance between the lead frames 11 and 12 at the side surface 20b, and a distance between lead frames 11 and 12 at the side surface 20c.

And, in the LED package 3, a p type layer (not shown) is formed in a lower portion of the LED chip 21R, and an n type layer (not shown) is formed in an upper portion of the LED chip 21R. Thus, the LED chip 21R passes current to the upper surface terminal from the lower surface terminal thereof, that is, to the lead frame 11 from the lead frame 12. Thus, the polarity of the LED chip 21R of the LED package 3 is reverse to the polarity of the LED chip 21R of the LED package 2. Unite with this, the polarities of the LED chips 21B and 21G of the LED package 3 are reverse to the polarities of the LED chips 21B and 21G of the LED package 2 too. Further, the Zener diode chips 43 and 44 are mounted on the lead frames 15 and 18 not on the lead frames 13 and 16.

In the LED package 3, since the portion of the belt-like region 41 other than the both ends thereof are narrow, the transparent resin body 20 can being prevent divided at the belt-like region 41, and a mechanical strength of the LED package 3 is high. On the other hand, in the both ends of the belt-like region 41, since a certain width is realized, a predetermined distance between extending portions is securable. Consequently, even if burrs occur on tip surfaces of the extending portions in dicing process, the short circuit between the lead frame 11 and the lead frame 12 can be prevented. Configurations, manufacturing methods, operations, and effects other than the above in the embodiment are similar to those of the above-described second embodiment.

Next, a forth embodiment will be described.

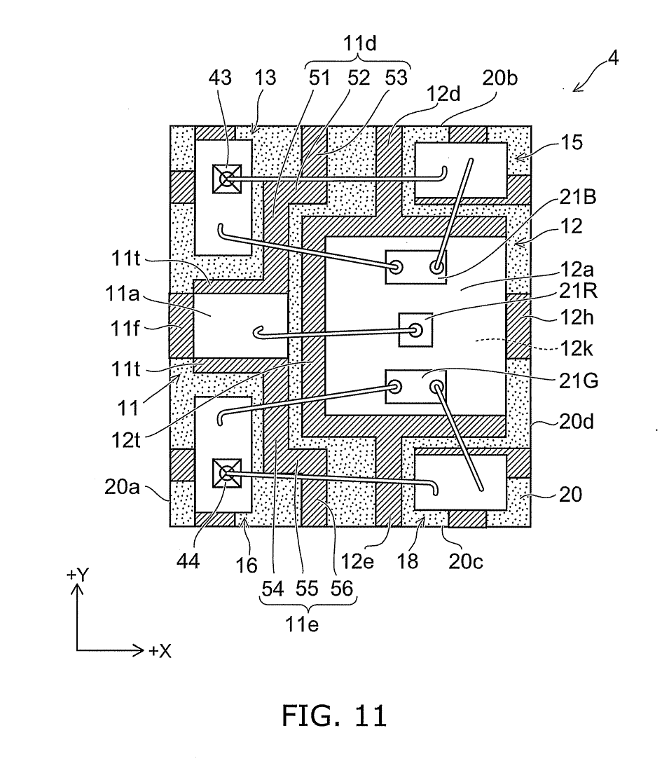

FIG. 11 is a plan view illustrating an LED package according to the embodiment.

As shown in FIG. 1, an LED package 4 according to the embodiment is different in the layout of the lead frames as compared with the above-described LED package 2 (refer to FIG. 9) according to the second embodiment.

Namely, in the LED package 4 according to the embodiment, the base 12a of the lead frame 12 projects toward the −X direction more than the extending portions 12d and 12e as compared with the LED package 2 (refer to FIG. 9) according to the second embodiment. Along with this, the protruding portion 12k also projects toward the −X direction, and the thin plate portion 12t is provided closer to the −X direction side than the protruding portion 12k. Hence, when viewed from the Z direction, a shape of the thin plate portion 12t is a U-shaped one open to the +X direction.

In addition, the base 11a of the lead frame 11 is retreated to the −X direction by a length corresponding to a length where the base 12a of the lead frame 12 is advanced to the −X direction, and the extending portions lid and 11e are bent in a crank shape so that they may wrap around an advanced portion of the base 12a. More specifically, in the extending portion lid, integrally formed are a portion 51 extending toward the +Y direction from the end of the +X direction side in an end edge oriented to the +Y direction of the base 11a, a portion 52 extending toward the +X direction from a tip of the portion 51, and a portion 53 extending toward the +Y direction from a tip of the portion 52, and a tip surface of the portion 53 is exposed at the side surface 20b of the transparent resin body 20. In the extending portion 11e, integrally formed are a portion 54 extending toward the −Y direction from the end of the +X direction side in an end edge oriented to the −Y direction of the base 11a, a portion 55 extending toward the +X direction from a tip of the portion 54, and a portion 56 extending toward the −Y direction from a tip of the portion 55, and a tip surface of the portion 56 is exposed at the side surface 20c of the transparent resin body 20.

As a result of this, the belt-like area 41 (refer to FIG. 9) on which no lead frame is arranged is not formed between the lead frames 11 and 12 in the LED package 4. Hence, in the LED package 4, there does not exist a plane perpendicular to a plane comprised of upper surfaces of the lead frames 11 to 18, i.e., the plane parallel to the Z direction and also the virtual plane that penetrates the transparent resin body 20 without passing through the lead frames. As a result of this, the transparent resin body 20 does not break along this plane, and a mechanical strength of the LED package 4 is high. Configurations, manufacturing methods, operations, and effects other than the above in the embodiment are similar to those of the above-described second embodiment.

It is to be noted that the above-described each embodiment and modified example thereof can be combined with one another to be implemented. For example, Zener diode chips may be provided in the above-described first embodiment similarly to the above-described second to forth embodiments. Meanwhile, Zener diode chips may not be provided in the above-described second to forth embodiments. In addition, the manufacturing method according to the above-described modified example of the first embodiment can be applied also in the above-described second to forth embodiments.

In addition, in the above-described each embodiment, has been shown the example where colors of light emitted by the three LED chips 21 are red (R), green (G), and blue (B), respectively, but the invention is not limited to this. Further, the number of LED chips has been set to be three in the above-described each embodiment, but the invention is not limited to this. For example, one more LED chip that emits green light (G) may be added to the three LED chips R, G, and B, and an LED chip that emits light of a color other than R, G, and B, for example, yellow or cyanogen may be added. Alternatively, the number of LED chips may be two depending on application. In addition, all of a plurality of LED chips to be mounted in one LED package may emit different colors of light from one another, a part of the LED chips may emit a same color of light and remaining LED chips may emit different colors of light, and all the LED chips may emit a same color. In the embodiment, when the number of LED chips are set to be n (n is a natural number), the number of lead frames are set to be (2×n).

According to the embodiments described above, a low cost LED package and a method for manufacturing the same can be achieved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An LED package comprising:
2n lead frames (n is a natural number) separated from one another;
n LED chips provided above the 2n lead frames, one terminal of each of the n LED chips being connected to each of the n lead frames, another terminal of each of the n LED chips being connected to each of other n lead frames;
a wire connected between the terminal and one of the lead frames; and
a resin body covering the n LED chips, the wire, and a part of each of the 2n lead frames,
the each of the 2n lead frames including;
a base having an upper surface and side surfaces, the upper surface and the side surfaces being covered with the resin body; and
a plurality of extending portions extending from the base, one of the extending portions having tip surface which is exposed at one side surface of the resin body, another of the extending portions, having tip surface which is exposed at another side surface of the resin body, the one side surface and the another side surface being perpendicular to each other, and
an outer shape of the resin body forming an outer shape of the LED package.

2. The package according to claim 1, wherein the n LED chips are mounted on one of the lead frames.

3. The package according to claim 2, wherein the one of the lead frames on which the n LED chips are mounted has three or more extending portions, tip surfaces of the three or more extending portions are exposed at three different side surface of the resin body.

4. The package according to claim 3, wherein when viewed from above, the one terminal and the another terminal are disposed inside a virtual polygonal region which is formed by connecting roots of the extending portions of the one of the lead frames on which the n LED chips are mounted.

5. The package according to claim 1, further comprising a Zener diode chip which is connected in parallel to one of the LED chips.

6. The package according to claim 1, wherein
two of the lead frames expose at a first side surface and a second side surface of the resin body, the second side surface does not contact with the first side surface,
a distance between the two lead frames in the resin body is shorter than a distance between the two lead frames at the first side surface and a distance between the two lead frames at the second side surface.

7. The package according to claim 1, wherein
upper surfaces of the 2n lead frames form a part of a plane, and
there does not exist a virtual plane that is perpendicular to the plane and that penetrates the resin body without passing through the lead frames.

8. The package according to claim 1, further comprising another lead frame which is not connected to any one of the terminals of the n LED chips.

9. The package according to claim 1, wherein
the n is 3 or more, and
the n LED chips include a red LED chip that emits red light, a green LED chip that emits green light, and a blue LED chip that emits blue light.

10. An LED package comprising:
2n lead frames (n is a natural number) separated from one another;
n LED chips provided above the 2n lead frames, one terminal of each of the n LED chips being connected to each of the n lead frames, another terminal of each of the n LED chips being connected to each of other n lead frames;
a wire connected between the terminal and one of the lead frames; and
a resin body covering the n LED chips, the wire, and a part of each of the 2n lead frames,
the each of the 2n lead frames including;
a base having an upper surface and side surfaces, the upper surface and the side surfaces being covered with the resin body; and
a extending portion extending from the base, a tip surface of the extending portion is exposed at a side surface of the resin body, the side surface being located in one direction when viewed from the base,
the wire being bonded to the lead frame by applying with ultrasonic wave, a direction of vibration of the ultrasonic wave being parallel to the one direction, and
an outer shape of the resin body forming an outer shape of the LED package.

11. The package according to claim 10, wherein the n LED chips are mounted on one of the lead frames.

12. The package according to claim 11, wherein the one of the lead frames on which the n LED chips are mounted has three or more extending portions, tip surfaces of the three or more extending portions are exposed at three different side surface of the resin body.

13. The package according to claim 10, wherein
upper surfaces of the 2n lead frames form a part of a plane, and
there does not exist a virtual plane that is perpendicular to the plane and that penetrates the resin body without passing through the lead frames.

14. The package according to claim 10, further comprising another lead frame which is not connected to any one of the terminals of the n LED chips.

15. A method for manufacturing an LED package comprising:
mounting n LED chips (n is a natural number) for each of a plurality of element regions provided on a lead frame sheet, connecting one terminal of each of the n LED chips to each of n lead frames of 2n lead frames, and connecting another terminal of each of the n LED chips to each of another n lead frames of the 2n lead frames, the lead frame sheet being formed of a conductive material, the lead frame sheet having a basic pattern including the plurality of element regions arranged in a matrix configuration, the lead frame sheet including support members which are provided in dicing regions between the element regions, each of the element regions including the 2n lead frames, each of the 2n lead frames being separated from one another, each of the 2n lead frames including a base and coupling portions, the base being separated from outer edges of the element regions, the coupling portions extending from the base and coupled to one of the support members,
forming a resin plate, the resin plate covering the LED chips and a part of the lead frame sheet, a lower surface of the resin plate being on a same plane as a lower surface of the lead frame sheet; and
dividing portions arranged in the element regions on the lead frame sheet and the resin plate into individual pieces by removing portions arranged in the dicing regions on the lead frame sheet and the resin plate, wherein
one of a plurality of the coupling portions reach one side of outer edges of the element regions, and another of the plurality of the coupling portions reach another side of outer edges of the element regions, the one side and the another side being perpendicular to each other,
the connecting the terminal includes;
applying ultrasonic wave to one end of a wire to bond the one end to the lead frame, and
bonding another end of the wire to the terminal, and
an outer shape of the portion divided into the individual pieces forms an outer shape of the LED package.

16. The method according to claim 15, further comprising
forming the lead frame sheet by selectively removing the conductive material from a conductive sheet made of the conductive material by selectively etching the conductive sheet from an upper surface side and a lower surface side thereof, respectively, stopping the etching at least from the lower surface side before the etching penetrates the conductive sheet.

17. The method according to claim 15, wherein
three or more of the coupling portions that reach three different sides of the outer edges of the element regions are formed on one of the lead frames included in the each basic pattern, and
the mounting n LED chips includes mounting each of the n LED chips on one of the lead frames so that the terminals are located in a virtual polygonal region which is formed by connecting roots of the three or more coupling portions in the base.

18. The method according to claim 15, wherein the n is 3.

19. A method for manufacturing an LED package comprising:
mounting n LED chips (n is a natural number) for each of a plurality of element regions provided on a lead frame sheet, connecting one terminal of each of the n LED chips to each of n lead frames of 2n lead frames, and connecting another terminal of each of the n LED chips to each of another n lead frames of the 2n lead frames, the lead frame sheet being formed of a conductive material, the lead frame sheet having a basic pattern including the plurality of element regions arranged in a matrix configuration, the lead frame sheet including support members which are provided in dicing regions between the element regions, each of the element regions including the 2n lead frames, each of the 2n lead frames being separated from one another, each of the 2n lead frames including a base and coupling portions, the base being separated from outer edges of the element regions, the coupling portions extending from the base and coupled to one of the support members,
forming a resin plate, the resin plate covering the LED chips and a part of the lead frame sheet, a lower surface of the resin plate being on a same plane as a lower surface of the lead frame sheet; and
dividing portions arranged in the element regions on the lead frame sheet and the resin plate into individual pieces by removing portions arranged in the dicing regions on the lead frame sheet and the resin plate, wherein
the coupling portion reaches one side of outer edges of the element regions, the side being located in one direction when viewed from the base,
the connecting the terminal includes;
applying ultrasonic wave to one end of a wire to bond the one end to the lead frame, a direction of vibration of the ultrasonic wave being parallel to the one direction, and
bonding another end of the wire to the terminal, and
an outer shape of the portion divided into the individual pieces forms an outer shape of the LED package.

20. The method according to claim 19, further comprising
forming the lead frame sheet by selectively removing the conductive material from a conductive sheet made of the conductive material by selectively etching the conductive sheet from an upper surface side and a lower surface side thereof, respectively, stopping the etching at least from the lower surface side before the etching penetrates the conductive sheet.
